(19) United States
(12) Patent Application Publication
(10) Pub. No.: US 2025/0351626 A1
(43) Pub. Date: Nov. 13, 2025

(54) DISPLAY DEVICE

(71) Applicant: Samsung Display Co., LTD., Yongin-si (KR)

(72) Inventors: Sung Kook PARK, Yongin-si (KR); Yun Su GU, Yongin-si (KR); Sang Hyun LEE, Yongin-si (KR)

(21) Appl. No.: 19/030,498

(22) Filed: Jan. 17, 2025

(30) Foreign Application Priority Data
May 7, 2024 (KR) 10-2024-0059586

(51) Int. Cl. H10H 20/84; H10H 29/49; H10H 29/80

(52) U.S. Cl. CPC H10H 20/84; H10H 29/49; H10H 29/8323

(57) ABSTRACT

A display device includes a first pixel electrode on a substrate, a first light emitting element on the first pixel electrode and including a semiconductor stack and a protective layer, and a common electrode on the substrate. A side surface of the semiconductor stack includes a first portion and a second portion that are different from each other, the protective layer is on the first portion of the side surface of the semiconductor stack, and the common electrode is on the second portion of the side surface of the semiconductor stack.

### CROSS-REFERENCE TO RELATED APPLICATION

The present application claims priority to and the benefit of Korean Patent Application No. 10-2024-0059586, filed on May 7, 2024, in the Korean Intellectual Property Office, the entire disclosure of which is incorporated by reference herein.

### BACKGROUND

### 1. Field

One or more embodiments of the present disclosure relate to a display device.

### 2. Description of the Related Art

As the information society develops, demands for display devices for displaying images are increasing in various forms. The display devices may be flat panel display devices such as liquid crystal displays, field light emitting displays, and light emitting displays.

The light emitting displays include an organic light emitting display including an organic light emitting diode (OLED) element as a light emitting element and a micro-light emitting display including a micro-light emitting diode element (hereinafter, referred to as a micro-light emitting element) as a light emitting element. Because micro-light emitting diode elements are made of inorganic materials, they have less deterioration issues and thus may have a longer life than organic light emitting diode (OLED) elements.

### SUMMARY

Aspects and features of embodiments of the present disclosure provide a display device with improved luminous efficiency.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a first pixel electrode on a substrate, a first light emitting element on the first pixel electrode and comprising a semiconductor stack and a protective layer, and a common electrode on the substrate. A side surface of the semiconductor stack includes a first portion and a second portion that are different from each other, the protective layer is on the first portion of the side surface of the semiconductor stack, and the common electrode is on the second portion of the side surface of the semiconductor stack.

The first portion may be closer to the first pixel electrode than the second portion.

The common electrode may be in contact with the second portion of the side surface of the semiconductor stack.

The semiconductor stack includes a first semiconductor layer, an active layer, and a second semiconductor layer stacked sequentially on the first pixel electrode, and the first portion of the side surface of the semiconductor stack includes the first semiconductor layer.

The second portion of the side surface of the semiconductor stack may include the second semiconductor layer.

The semiconductor stack may further include a third semiconductor layer on the second semiconductor layer, and the second portion of the side surface of the semiconductor stack includes the third semiconductor layer.

The display device may further include a capping layer on the first light emitting element and the common electrode.

The capping layer may be on the second portion of the side surface of the semiconductor stack.

A thickness of the second portion of the side surface of the semiconductor stack may be 50% or more of a sum of thicknesses of the second semiconductor layer and the third semiconductor layer of the first light emitting element.

A thickness of the second portion of the side surface of the semiconductor stack may be 1.1 to 2.7 μm.

The common electrode may include one or more of indium tin oxide (ITO), zinc indium tin oxide (ZITO), and/or indium zinc oxide (IZO).

The first light emitting element may further include a contact electrode between the first pixel electrode and the semiconductor stack, and the contact electrode may include a conductive carbon material.

The first light emitting element may further include a metal layer between the semiconductor stack and the first pixel electrode, the protective layer may partially cover a lower surface of the metal layer to expose at least a portion of the lower surface of the metal layer, and the contact electrode may be in contact with the exposed lower surface of the metal layer.

The display device may further include a second pixel electrode on the substrate and spaced from the first pixel electrode, and a second light emitting element on the second pixel electrode and including a semiconductor stack and a protective layer. The common electrode may be on a side surface of the second light emitting element.

The display device may further include a power supply line on the substrate and spaced from the first pixel electrode, and an organic layer between the power supply line and the common electrode. The organic layer may include a common connection hole penetrating the organic layer, and the power supply line and the common electrode may be electrically connected through the common connection hole.

According to one or more embodiments of the present disclosure, there is provided a display device including a plurality of pixel electrodes on a substrate, a plurality of light emitting elements on the plurality of pixel electrodes, respectively, and a common electrode on the substrate and being in contact with side surfaces of the light emitting elements. Each of the plurality of light emitting elements includes a body portion including a metal layer, a first semiconductor layer, an active layer, a second semiconductor layer and a third semiconductor layer stacked sequentially and a protective layer on an edge of a lower surface of the body portion, and the protective layer extends on the edge of the lower surface of the body portion to cover a portion of a side surface of the body portion and exposes an other portion of the side surface of the body portion.

The side surface of the body portion that is not covered with the protective layer may be in contact with the common electrode.

A thickness of the side surface of the body portion not covered with the protective layer may be 40% or more of a thickness of the body portion.

At least a portion of a side surface of the second semiconductor layer may be exposed without being covered with the protective layer.

The display device may further include a capping layer on upper and side surfaces of the third semiconductor layer.

According to one or more embodiments of the present disclosure, there is provided a electronic device that includes a display device configured to provide an image, a processor configured to provide an image data signal into the display device. The display device includes a first pixel electrode on a substrate, a first light emitting element on the first pixel electrode and comprising a semiconductor stack and a protective layer, and a common electrode on the substrate. A side surface of the semiconductor stack includes a first portion and a second portion that are different from each other. The protective layer is on the first portion of the side surface of the semiconductor stack, and the common electrode is on the second portion of the side surface of the semiconductor stack.

In a display device according to embodiments, a common electrode is connected to side surfaces of the light emitting element. Therefore, a light emitting area may be increased, and resistance may be lowered. Accordingly, the luminous efficiency of the display device can be improved.

### BRIEF DESCRIPTION OF THE DRAWINGS

The above and other embodiments and features of the present disclosure will become more apparent by describing embodiments thereof with reference to the attached drawings, in which:

FIG. 1 is a perspective view of a display device according to one or more embodiments;

FIG. 2 is a layout view of the display device according to one or more embodiments;

FIG. 3 is a block diagram of the display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a cross-sectional view illustrating an example of a cross section of a display panel corresponding to the line 11-11′ of FIG. 5;

FIG. 7 is a detailed cross-sectional view of an example of an area A of FIG. 6;

FIG. 8 is a plan view illustrating the overlap of a light emitting element and a metal layer;

FIG. 9 is an enlarged cross-sectional view of a portion of a display panel according to one or more embodiments;

FIGS. 10-16 are cross-sectional views sequentially illustrating a process of manufacturing a display device according to one or more embodiments;

FIG. 17 is an example view of a smart watch including a display device according to one or more embodiments;

FIGS. 18 and 19 are example views of a virtual reality (VR) device including a display device according to one or more embodiments;

FIG. 20 is an example view of a VR device including a display device according to one or more embodiments;

FIG. 21 is an example view illustrating a vehicle instrument cluster and center fascia including display devices according to one or more embodiments; and

FIG. 22 is an example view of a transparent display device including a display device according to one or more embodiments.

FIG. 23 is a block diagram of an electronic device according to one or more embodiments of the present disclosure.

FIG. 24 is a schematic diagram of an electronic device according to various embodiments of the present disclosure.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

Specific embodiments are described below with reference to the attached drawings.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

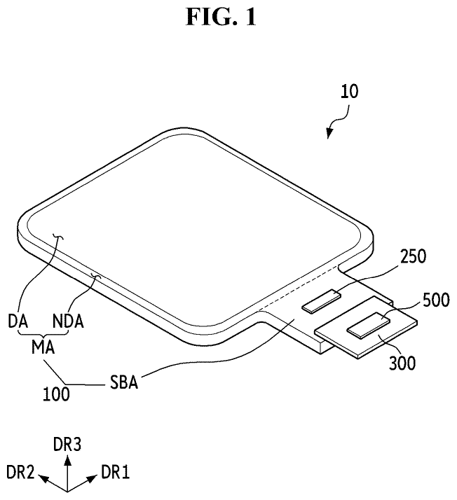

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or a micro-or nano-light emitting display device using a micro-or nano-light emitting diode. A case where the display device 10 is a micro-or nano-light emitting display device will be mainly described below, but the present disclosure is not limited thereto. For ease of description, a micro-or nano-light emitting diode will be referred to as a light emitting element.

The display device 10 includes a display panel 100, a display driver 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, or an elliptical shape. The display panel 100 may be formed flat, but embodiments are not limited thereto. For example, the display panel 100 may include a curved portion formed at left and right ends and having a constant or varying curvature. In addition, the display panel 100 may be formed to be flexible so that it can be curved, bent, folded, and/or rolled.

The display panel 100 may include a main area MA and a sub-area SBA.

The main area MA may include a display area DA, which displays an image and a non-display area NDA disposed around the display area DA along an edge or a periphery of the display area DA. The display area DA may include a plurality of pixels that displays an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driver 250 may be disposed in the sub-area SBA.

The display driver 250 may generate signals and voltages for driving the display panel 100. The display driver 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driver 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driver 250. The display panel 100 and the display driver 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

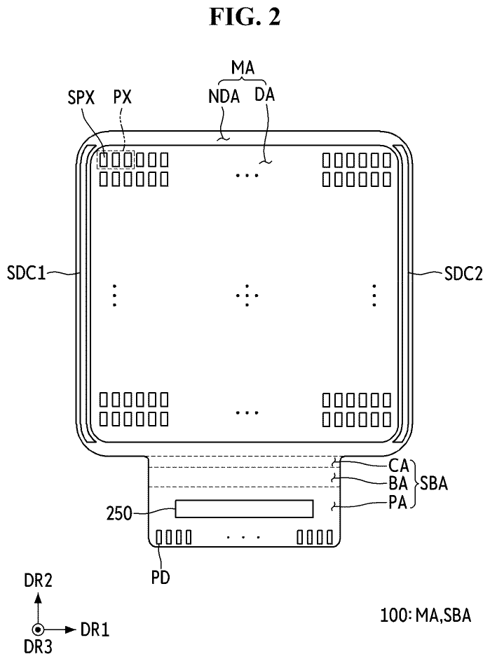

FIG. 2 is a layout view of the display device 10 according to one or more embodiments. FIG. 2 illustrates a state in which the sub-area SBA is unfolded.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-

display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may be in contact with the non-display area NDA of the main area MA, and the other side of the connection area CA may be in contact with the bending area BA.

The pad area PA is an area where pads PD and the display driver 250 are disposed. The display driver 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may be in contact with the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may be in contact with the connection area CA, and the other side of the bending area BA may be in contact with the pad area PA.

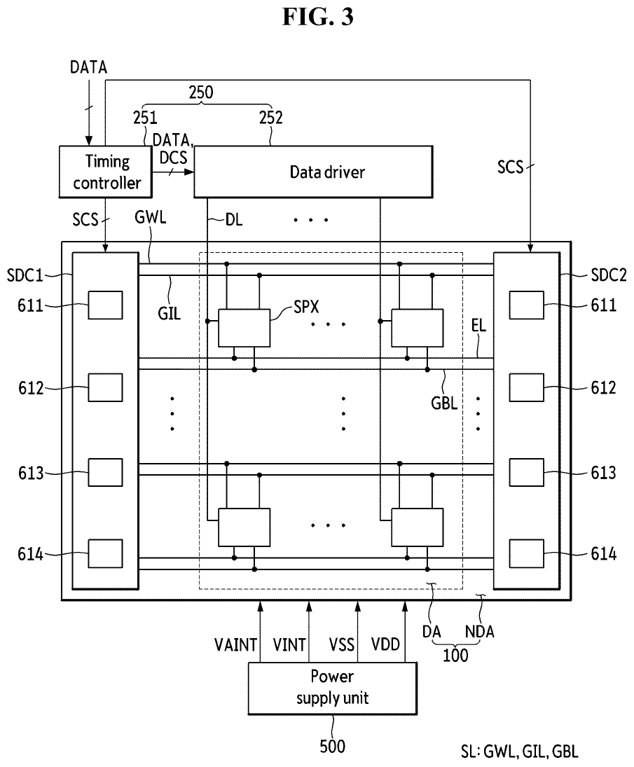

FIG. 3 is a block diagram of the display device 10 according to one or more embodiments.

Referring to FIG. 3, the display area DA includes a plurality of pixels PX each of the pixels PX may be including a plurality of subpixels SPX, a plurality of scan lines SL, a plurality of light emitting control lines EL, and a plurality of data lines DL.

The pixels PX may be arranged in a matrix form along the first direction DR1 and the second direction DR2. For example, the pixels PX may be arranged along rows and columns of a matrix along the first direction DR1 and the second direction DR2. The scan lines SL and the light emitting control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of a plurality of subpixels SPX may be connected to one of the write scan lines GWL, one of the initialization scan lines GIL, one of the bias scan lines GBL, one of the light emitting control lines EL, and one of the data lines DL. In one or more embodiments, each of a plurality of subpixels SPX may also be connected to one of control scan lines. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driver 250.

Each of the first scan driver SDC1 and the second scan driver SDC2 may include a write scan signal output unit 611, an initialization scan signal output unit 612, a bias scan signal output unit 613, and a light emitting control signal output unit 614. Each of the write scan signal output unit 611, the initialization scan signal output unit 612, the bias scan signal output unit 613, and the light emitting control signal output unit 614 may receive a scan timing control signal SCS from a timing controller 251.

The write scan signal output unit 611 may generate write scan signals according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The bias scan signal output unit 613 may generate bias scan signals according to the scan timing control signal SCS and sequentially output the bias scan signals to the bias scan lines GBL. The light emitting control signal output unit 614 may generate light emitting control signals according to the scan timing control signal SCS and sequentially output the light emitting control signals to the light emitting control lines EL.

The display driver 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage supplied from the outside. For example, the power supply unit 500 may generate a first power supply voltage VDD, a second power supply voltage VSS, a third power supply voltage VINT and a fourth power supply voltage VAINT and supply them to the display panel 100.

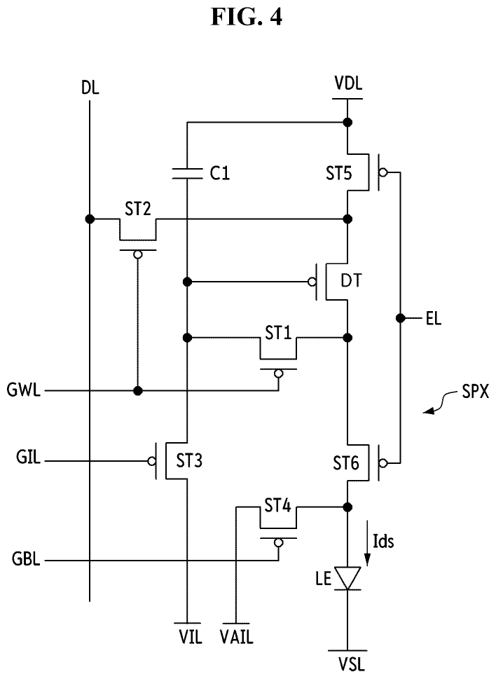

FIG. 4 is an equivalent circuit diagram of a subpixel SPX according to one or more embodiments.

Referring to FIG. 4, the subpixel SPX according to one or more embodiments may be connected to scan lines GWL, GIL, and GBL, a light emitting control line EL, and a data line DL. For example, the subpixel SPX may be connected to a write scan line GWL, an initialization scan line GIL, a bias scan line GBL, the light emitting control line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light emitting element LE may be a micro-light emitting diode.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power supply line VSL to which the second power supply voltage VSS is applied.

The capacitor C1 is formed between the gate electrode of the driving transistor DT and a first power supply line VDL to which the first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power supply line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors may be connected to the light emitting control line EL. Because the first through sixth transistors ST1 through ST6 are formed as p-type MOSFETs, they may be turned on when a scan signal of a gate-low voltage and a light emitting control signal of a gate-low voltage are transmitted to the initialization scan line GIL, the write scan line GWL, the bias scan line GBL, and the light emitting control line EL. One electrode of the third transistor ST3 may be connected to a first initialization voltage line VIL to which the third power supply voltage VINT (see FIG. 3) is applied, and one electrode of the fourth transistor ST4 may be connected to a second initialization voltage line VAIL to which the fourth power supply voltage VAINT (see FIG. 3) is applied. The third power supply voltage VINT (see FIG. 3) and the fourth power supply voltage VAINT (see FIG. 3) may be different voltages. In addition, the third power supply voltage VINT (see FIG. 3) and the fourth power supply voltage VAINT (see FIG. 3) may be at a lower level than the first power supply voltage VDD and may be at a higher level than the second power supply voltage VSS.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. In this case, the active layer of each of the driving transistor DT, the second transistor ST2, the fourth transistor ST4, the fifth transistor ST5 and the sixth transistor ST6 formed as p-type MOSFETs may be made of polysilicon, and the active layer of each of the first transistor ST1 and the third transistor ST3 formed as n-type MOSFETs may be made of an oxide semiconductor. In addition, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and a light emitting control signal of a gate-low voltage.

Alternatively, the fourth transistor ST4 may be formed as an n-type MOSFET, and the other transistors DT, ST1, ST2, ST3, ST5, and ST6 may be formed as p-type MOSFETs. In this case, the active layer of the fourth transistor ST4 may be made of an oxide semiconductor, and the active layer of each of the other transistors DT, ST1, ST2, ST3, ST5, and ST6 may be made of polysilicon. In addition, the fourth transistor ST4 may be turned on in response to a scan signal of a gate-high voltage, and the other transistors DT, ST1, ST2, ST3, ST5, and ST6 may be turned on in response to a scan signal of a gate-low voltage and a light emitting control signal of a gate-low voltage.

Alternatively, the first through sixth transistors ST1 through ST6 and the driving transistor DT may all be formed as n-type MOSFETs. In this case, the first through sixth transistors ST1 through ST6 and the driving transistor DT may each have an active layer made of an oxide semiconductor and may be turned on in response to a scan signal of a gate-high voltage and a light emitting control signal.

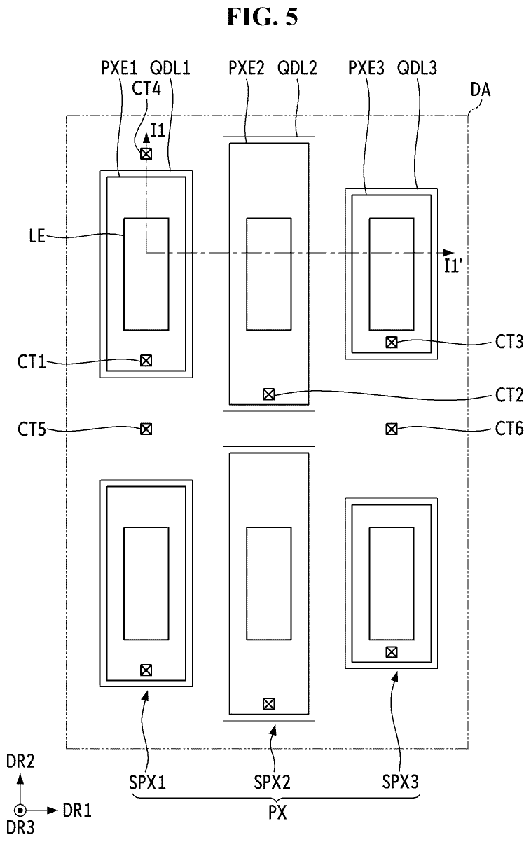

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX, the first subpixel SPX1, the second subpixel SPX2, and the third subpixel SPX3 may be arranged along the first direction DR1.

When each of the pixels PX includes three subpixels SPX1 through SPX3, the first subpixel SPX1 may output first light, the second subpixel SPX2 may output second light, and the third subpixel SPX3 may output third light. Here, the first light may be light in a red wavelength band, the second light may be light in a green wavelength band, and the third light may be light in a blue wavelength band. For example, the red wavelength band may indicate that a main peak wavelength of light is included in a wavelength band of about 600 to 750 nm, the green wavelength band may indicate that a main peak wavelength of light is included in a wavelength band of about 480 to 560 nm, and the blue wavelength band may indicate that a main peak wavelength of light is included in a wavelength band of about 370 to 460 nm.

Alternatively, when each of the pixels PX includes four subpixels, a first subpixel may output first light, a second subpixel and a fourth subpixel may output second light, and a third subpixel may output third light. Alternatively, the first subpixel may output first light, the second subpixel may output second light, the third subpixel may output third light, and the fourth subpixel may output fourth light. Here, the fourth light may be white light.

The first subpixel SPX1 includes a first pixel electrode PXE1, a light emitting element LE, and a first light conversion layer QDL1. The second subpixel SPX2 includes a second pixel electrode PXE2, a light emitting element LE, and a second light conversion layer QDL2. The third subpixel SPX3 includes a third pixel electrode PXE3, a light emitting element LE, and a light transmission layer (or a third light conversion layer) TPL.

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. In addition, because the first light conversion layer QDL1 may convert light whereas the light transmission layer TPL transmits light of the light emitting element LE as it is, the area of the first pixel electrode PXE1 may be larger than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to the first electrode of the fourth transistor ST4 (see FIG. 4) and the second electrode of the sixth transistor ST6 (see FIG. 4) of a corresponding subpixel.

The light emitting elements LE may be disposed on the pixel electrodes PXE1 through PXE3, respectively. The same number of light emitting elements LE may be disposed on each of the pixel electrodes PXE1 through PXE3. For example, one light emitting element LE may be disposed on each of the pixel electrodes PXE1 through PXE3. However, the present disclosure is not limited thereto, and a plurality of light emitting elements LE may also be disposed in the same number on each of the pixel electrodes PXE1 through PXE3. The light emitting elements LE may emit third light, for example, light in the blue wavelength band, but the present disclosure is not limited thereto. If the light emitting element LE of the first subpixel SPX1 emits first light, the light emitting element LE of the second subpixel SPX2 emits second light, and the light emitting element LE of the third subpixel SPX3 emits third light, the light conversion layers QDL1 and QDL2 and the light transmission layer TPL may be omitted.

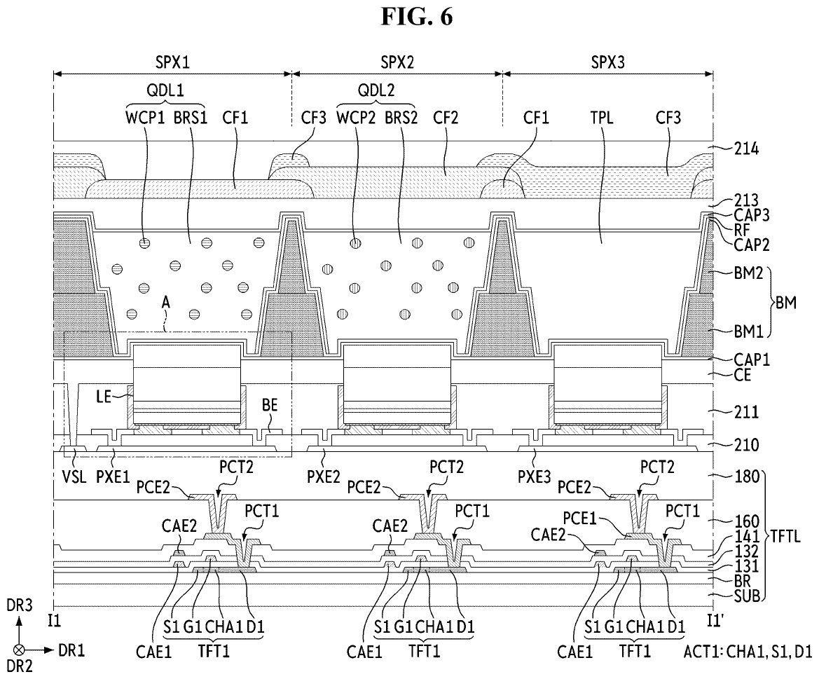

A common electrode CE (see FIG. 6) may be disposed on the pixel electrodes PXE1 through PXE3 in the display area DA, but may expose upper surfaces of the light emitting elements LE. The common electrode CE may be electrically connected to a second power supply line VSL (see FIG. 6) through a common connection hole CT4, CT5, or CT6.

The first light conversion layer QDL1 may completely overlap the first pixel electrode PXE1 and the light emitting element LE of the first subpixel SPX1. The area of the first light conversion layer QDL1 may be larger than the area of the first pixel electrode PXE1. The first light conversion layer QDL1 may convert or shift a peak wavelength of incident light into another specific peak wavelength and output light of the specific peak wavelength. For example, the first light conversion layer QDL1 may convert or shift third light emitted from the light emitting element LE of the first subpixel SPX1 into first light.

The second light conversion layer QDL2 may completely overlap the second pixel electrode PXE2 and the light emitting element LE of the second subpixel SPX2. The area of the second light conversion layer QDL2 may be larger than the area of the second pixel electrode PXE2. The second light conversion layer QDL2 may convert or shift a peak wavelength of incident light into another specific peak wavelength and output light of the specific peak wavelength. For example, the second light conversion layer QDL2 may convert or shift third light emitted from the light emitting element LE of the second subpixel SPX2 into second light.

The light transmission layer TPL may completely overlap the third pixel electrode PXE3 and the light emitting element LE of the third subpixel SPX3. The light transmission layer TPL may transmit incident light as it is. For example, the light transmission layer TPL may transmit third light emitted from the light emitting element LE of the third subpixel SPX3 as it is.

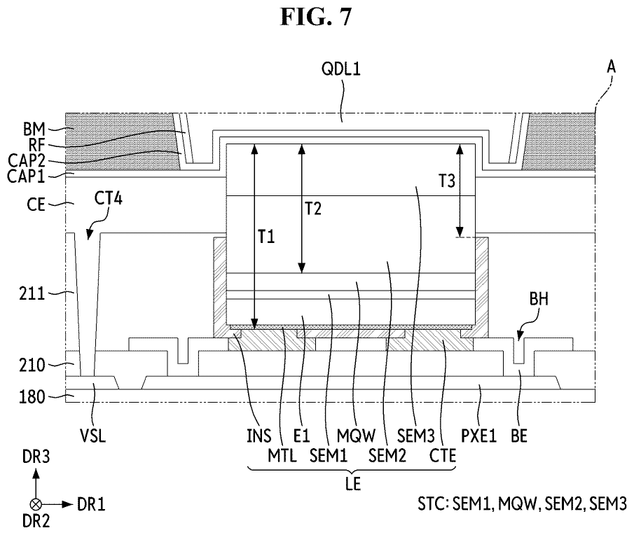

FIG. 6 is a cross-sectional view illustrating an example of a cross section of the display panel 100 corresponding to the line 11-11′ of FIG. 5. FIG. 7 is a detailed cross-sectional view of an example of an area A of FIG. 6.

Referring to FIGS. 6 and 7, a substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of a thin-film transistor layer TFTL and light emitting elements LE on the thin-film transistor layer TFTL from moisture introduced through the substrate SUB which is vulnerable to moisture penetration. The barrier layer BR may be composed of a plurality of inorganic layers stacked alternately.

Thin-film transistors TFT1 may be disposed on the barrier layer BR. Each of the thin-film transistors TFT1 may be one of the fourth transistor ST4 or the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3 which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 6, the first gate electrodes G1 and the first capacitor electrodes CAE1 are spaced (e.g., spaced apart) from each other. However, when each of the thin-film transistors TFT1 is the driving transistor DT of FIG. 4, the first gate electrodes G1 and the first capacitor electrodes CAE1 may also be electrically or physically connected to each other. Alternatively, when each of the thin-film transistors TFT1 is one of the first through sixth transistors ST1 through ST6 of FIG. 4, the first gate electrodes G1 and the first capacitor electrodes CAE1 may not be electrically or physically connected to each other.

A second gate insulating layer 132 may be disposed on the first gate electrodes G1 of the thin-film transistors TFT1 and the first capacitor electrodes CAE1, and the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 connected to the gate electrode G1 of the thin-film transistors TFT1 in the third direction DR3. Because the second gate insulating layer 132 has a suitable dielectric constant (e.g., a predetermined dielectric constant), capacitors C1 (see FIG. 4) may be formed by the first capacitor electrodes CAE1, the second capacitor electrodes CAE2, and the second gate insulating layer 132 disposed between them.

An interlayer insulating layer 141 may be disposed on the second capacitor electrodes CAE2 and the second gate insulating layer 132.

A first data metal layer may be disposed on the interlayer insulating layer 141. The first data metal layer may include first source connection electrodes PCE1. The first source connection electrodes PCE1 may be connected to the first drain regions D1 of the first active layers ACT1 through first source contact holes PCT1 penetrating the first gate insulating layer 131, the second gate insulating layer 132, and the interlayer insulating layer 141.

A first planarization layer 160 may be disposed on the first source connection electrodes PCE1 and the interlayer insulating layer 141 to flatten steps caused by the thin-film transistors TFT1.

A second data metal layer may be disposed on the first planarization layer 160. The second data metal layer may include second source connection electrodes PCE2. The second source connection electrodes PCE2 may be connected to the first source connection electrodes PCE1 through second source contact holes PCT2 penetrating the first planarization layer 160.

A second planarization layer 180 may be disposed on the second source connection electrodes PCE2 and the first planarization layer 160.

The barrier layer BR, the first gate insulating layer 131, the second gate insulating layer 132, and the interlayer insulating layer 141 may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The first gate metal layer, the second gate metal layer, the first data metal layer, and the second data metal layer may each be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The first planarization layer 160 and the second planarization layer 180 may be made of an organic layer such as acryl resin, epoxy resin, phenolic resin, polyamide resin, and/or polyimide resin.

A light emitting element layer may be disposed on the second planarization layer 180. The light emitting element layer may include pixel electrodes PXE1 through PXE3, a second power supply line VSL, light emitting elements LE, a common electrode CE, and organic layers 210 and 211.

A pixel electrode layer may be disposed on the second planarization layer 180. The pixel electrode layer may include a first pixel electrode PXE1, a second pixel electrode PXE2, a third pixel electrode PXE3, and the second power supply line VSL.

Each of the pixel electrodes PXE1 through PXE3 may be connected to a second source connection electrode PCE2 through a pixel connection hole CT1/CT2/CT3 (see FIG. 5) penetrating the second planarization layer 180. Each of the pixel electrodes PXE1 through PXE3 may be connected to the first source region S1 or the first drain region D1 of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The second power supply voltage VSS controlled by the driving transistor DT may be applied to the second power supply line VSL. The common electrode CE may be connected to the second power supply line VSL through a common connection hole CT4, CT5, or CT6. In the drawings, the second power supply line VSL may be formed together with the pixel electrodes PXE1 through PXE3. In one or more embodiments, the second power supply line VSL may not extend on the second planarization layer 180 and may be connected to the second data metal layer on the first planarization layer 160 through holes in some areas.

The pixel electrode layer may be a single layer or a multilayer made of molybdenum (Mo), aluminum (AI), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3.

A first organic layer 210 may be disposed on each of the pixel electrodes PXE1 through PXE3 and the second power supply line VSL. The first organic layer 210 temporarily fixes or attaches a plurality of light emitting elements LE to prevent the light emitting elements LE from tilting or falling during a process of transferring the light emitting elements LE to the display panel 100. That is, the first organic layer 210 may be a layer for temporarily attaching a plurality of light emitting elements LE onto the pixel electrodes PXE1 through PXE3, respectively. To facilitate the temporary adhesion, the first organic layer 210 may be thicker than each of the pixel electrodes PXE1 through PXE3 and thicker than contact electrodes CTE.

The first organic layer 210 may cover the pixel electrodes PXE1 through PXE3 and the second power supply line VSL, but may have a connection hole BH that exposes at least a portion of each of the pixel electrodes PXE1 through PXE3 and a first common connection hole CT4 that exposes at least a portion of the second power supply line VSL.

The first organic layer 210 may be a photosensitive organic layer such as photoresist. Alternatively, the first organic layer 210 may be made of acryl resin, epoxy resin, phenolic resin, polyamide resin, and/or polyimide resin.

A plurality of light emitting elements LE may be disposed on the first organic layer 210. In FIG. 6, each of the light emitting elements LE is a hybrid type micro-light emitting diode. The hybrid type micro-light emitting diode may be structured like a vertical type micro-light emitting diode in which a first semiconductor layer SEM1, an active layer MQW, and a second semiconductor layer SEM2 are sequentially disposed in the third direction DR3 which is a vertical direction. However, the hybrid type micro-light emitting diode may further include a third semiconductor layer SEM3, like a flip type micro-light emitting diode.

Each of the light emitting elements LE may be made of an inorganic material such as gallium nitride (GaN). Each of the light emitting elements LE may have a length of several to hundreds of μm in each of the first direction DR1, the second direction DR2, and the third direction DR3. For example, each of the light emitting elements LE may have a length of about 100 μm or less in each of the first direction DR1, the second direction DR2, and the third direction DR3.

Each of the light emitting elements LE may be grown on a semiconductor substrate such as a silicon substrate and/or a sapphire substrate. The light emitting elements LE may be directly transferred from the semiconductor substrate onto the pixel electrodes PXE1 through PXE3 of the display panel 100. Alternatively, the light emitting elements LE may be transferred onto the pixel electrodes PXE1 through PXE3 of the display panel 100 through an electrostatic method using an electrostatic head or a stamp method using an elastic polymer material, such as PDMS or silicon, as a transfer substrate.

Each of the light emitting elements LE may include a metal layer MTL, a conductive layer E1, a semiconductor stack STC, a contact electrode CTE, and a protective layer INS. The semiconductor stack STC may include a first semiconductor layer SEM1, an active layer MQW, a second semiconductor layer SEM2, and a third semiconductor layer SEM3 sequentially disposed in the third direction DR3. A body portion of each of the light emitting elements LE may include the metal layer MTL, the conductive layer E1, and the semiconductor stack STC. The body portion of each of the light emitting elements LE may be a light emitting element LE without the protective layer INS and the contact electrode CTE.

The metal layer MTL may be disposed on a lower surface of the conductive layer E1. The metal layer MTL reflects light emitted from the active layer MQW to an upper surface of the display device 10. The metal layer MTL may include a metal material having high reflectivity, such as aluminum (Al) and/or silver (Ag).

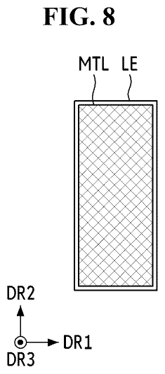

FIG. 8 is a plan view illustrating the overlap of a light emitting element LE and the metal layer MTL. The area of the metal layer MTL may be similar to the area of the light emitting element LE, but may be slightly smaller than the area of the light emitting element LE. The area of the light emitting element LE may be the same as the area of the first semiconductor layer SEM1, the active layer MQW, the second semiconductor layer SEM2 or the third semiconductor layer SEM3 and may be a light emitting area. Because the area of the metal layer MTL is similar to the light emitting area, light extraction efficiency can be improved or maximized. The metal layer MTL may cover a central portion of the light emitting element LE and expose only edges of the light emitting element LE.

The conductive layer E1 may be disposed on a lower surface of the first semiconductor layer SEM1. Although the conductive layer E1 covers the entire lower surface of the first semiconductor layer SEM1 in FIG. 7, the present disclosure is not limited thereto. For example, the conductive layer E1 may also be disposed on a portion of the lower surface of the first semiconductor layer SEM1. The conductive layer E1 may include molybdenum (Mo), aluminum (AI), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may be made of a semiconductor material layer, for example, gallium nitride (GaN) doped with a first conductivity type dopant or a p-type dopant such as magnesium (Mg), zinc (Zn), calcium (Ca), strontium (Sr), and/or barium (Ba).

The active layer MQW may be disposed on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but the present disclosure is not limited thereto. Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

When the active layer MQW includes indium gallium nitride (InGaN), the color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE that emits third light (light in the blue wavelength band) may be about 10 to 20 wt %.

The second semiconductor layer SEM2 may be disposed on the active layer MQW. The second semiconductor layer SEM2 may be made of a semiconductor material layer, for example, gallium nitride (GaN) doped with a second conductivity type dopant or an n-type dopant such as silicon (Si), germanium (Ge), and/or tin (Sn).

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of InGaN and/or GaN. The superlattice layer can be omitted.

The third semiconductor layer SEM3 may be disposed on the second semiconductor layer SEM2. The third semiconductor layer SEM3 may be a semiconductor material layer having an n-type dopant lower than a suitable threshold value (e.g., a predetermined threshold value) and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant lower than a suitable threshold value (e.g., a predetermined threshold value).

The protective layer INS may be disposed on side (e.g., outer peripheral surface) and lower surfaces of each light emitting element LE to protect the light emitting element LE. The protective layer INS may be disposed on side surfaces (e.g., outer peripheral surfaces) of the first semiconductor layer SEM1, side surfaces (e.g., outer peripheral surfaces) of the active layer MQW, and side surfaces (e.g., outer peripheral surfaces) of the second semiconductor layer SEM2, but may expose at least a portion of the side surfaces of the third semiconductor layer SEM3 and/or at least a portion of the side surfaces of the second semiconductor layer SEM2. An area where the side surfaces of the second semiconductor layer SEM2 and the third semiconductor layer SEM3 are exposed without being covered with the protective layer INS may be electrically connected to the common electrode CE to receive the second power supply voltage VSS. A portion covered with the protective layer INS in the side surfaces (e.g., outer peripheral surfaces) of each light emitting element LE, side surfaces (e.g., outer peripheral surfaces) of the body portion of each light emitting element LE, or side surfaces (e.g., outer peripheral surfaces) of the semiconductor stack STC may be defined as a first portion, and a portion not covered with the protective layer INS in the side surfaces (e.g., outer peripheral surfaces) of each light emitting element LE, the side surfaces (e.g., outer peripheral surfaces) of the body portion of each light emitting element LE, or the side surfaces (e.g., outer peripheral surfaces) of the semiconductor stack STC may be defined as a second portion.

The protective layer INS covers a lower surface of the metal layer MTL, but may expose at least a portion of the lower surface of the metal layer MTL. The exposed lower surface of the metal layer MTL may be electrically connected to the contact electrode CTE. The protective layer INS may be disposed not only on edges of the lower surface of the metal layer MTL, but also on a center spaced (e.g., spaced apart) from the edges. The protective layer INS also covers the side surfaces of the conductive layer E1.

In an embodiment, a thickness T3 of the area where the side surfaces (e.g., outer peripheral surfaces) of the second semiconductor layer SEM2 and the third semiconductor layer SEM3 are exposed without being covered with the protective layer INS may be 50% or more of the sum T2 of thicknesses of the second semiconductor layer SEM2 and the third semiconductor layer SEM3. The thickness T3 of the area where the side surfaces of the second semiconductor layer SEM2 and the third semiconductor layer SEM3 are exposed without being covered with the protective layer INS may be 99% or less of the sum T2 of the thicknesses of the second semiconductor layer SEM2 and the third semiconductor layer SEM3. The thickness T3 of the area where the side surfaces of the second semiconductor layer SEM2 and the third semiconductor layer SEM3 are exposed without being covered with the protective layer INS may be 55 to 90% of the sum T2 of the thicknesses of the second semiconductor layer SEM2 and the third semiconductor layer SEM3. In the above range, the side surfaces of the second semiconductor layer SEM2 having relatively lower resistance than the third semiconductor layer SEM3 may be exposed, and the common electrode CE may be in contact with the second semiconductor layer SEM2 to enable a low-resistance connection and protect the semiconductor stack STC located in a lower portion of each light emitting element LE. The entire side surfaces of the high-resistance third semiconductor layer SEM3 may be exposed without being covered with the protective layer INS. The thickness T3 of the area where the side surfaces of the second semiconductor layer SEM2 and the third semiconductor layer SEM3 are exposed without being covered with the protective layer INS may be a thickness of the second portion of each side surface of the semiconductor stack STC, a thickness of the second portion of each side surface of the body portion of each light emitting element LE, or a thickness of the second portion of each side surface of each light emitting element LE.

In one or more embodiments, the thickness T3 of the area where the side surfaces of the second semiconductor layer SEM2 and the third semiconductor layer SEM3 are exposed without being covered with the protective layer INS may be 40% or more of a thickness T1 of the body portion of each light emitting element LE. The thickness T3 of the area where the side surfaces of the second semiconductor layer SEM2 and the third semiconductor layer SEM3 are exposed without being covered with the protective layer INS may be 99% or less of the thickness T1 of the body portion of each light emitting element LE. The thickness T3 of the area where the side surfaces of the second semiconductor layer SEM2 and the third semiconductor layer SEM3 are exposed without being covered with the protective layer INS may be 50 to 80% of the thickness T1 of the body portion of each light emitting element LE. In one or more embodiments, the thickness T3 of the area where the side surfaces of the second semiconductor layer SEM2 and the third semiconductor layer SEM3 are exposed without being covered with the protective layer INS may be 1.1 to 2.7 μm. The body portion of each light emitting element LE may include the metal layer MTL, the conductive layer E1, and the semiconductor stack STC.

The protective layer INS may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The contact electrode CTE may be disposed between the metal layer MTL and the first organic layer 210. The contact electrodes CTE may be in contact with the first organic layer 210 and a connection electrode BE.

Although the contact electrode CTE of each light emitting element LE is disposed on the first organic layer 210 in FIGS. 6 and 7, the present disclosure is not limited thereto. For example, the first organic layer 210 may be disposed on a lower surface and a portion of each side surface of the contact electrode CTE of each light emitting element LE. Alternatively, the first organic layer 210 may be disposed on the side surfaces of the conductive layer E1 of each light emitting element LE.

Alternatively, the first organic layer 210 may be disposed on the side surfaces of the first semiconductor layer SEM1, the side surfaces of the active layer MQW, and the side surfaces of the second semiconductor layer SEM2 of each light emitting element LE. In this case, the first organic layer 210 may be disposed on a portion of each side surface of the second semiconductor layer SEM2.

At least a portion of the contact electrode CTE may be connected to the metal layer MTL exposed without being covered by the protective layer INS. At least a portion of the contact electrode CTE may be in contact with the metal layer MTL. In one or more embodiments, the contact electrode CTE and the metal layer MTL may be in contact with each other in a plurality of areas, and the areas may be spaced (e.g., spaced apart) from each other. Accordingly, even if one area of the contact electrode CTE is not connected to the metal layer MTL due to a process error, another area of the contact electrode CTE may be connected to the metal layer MTL, thereby preventing a light emitting element LE from not lighting up.

The contact electrode CTE may include a conductive carbon material. The contact electrode CTE may be a photoresist that can be patterned by light. The photoresist may have conductivity when subjected to pressure. The contact electrode CTE including the photoresist may have conductivity by receiving force from the metal layer MTL thereon and may be electrically connected to a pixel electrode PXE1, PXE2, or PXE3 through the connection electrode BE.

The connection electrode BE connects the contact electrode CTE of each light emitting element LE to one of the pixel electrodes PXE1 through PXE3. The connection electrode BE may be connected to one of the pixel electrodes PXE1 through PXE3 exposed through the connection hole BH penetrating the first organic layer 210. In addition, the connection electrode BE may be disposed on an upper surface of the first organic layer 210 and the side surfaces of the contact electrode CTE. In addition, the connection electrode BE may be disposed on a portion of the side surfaces of each light emitting element LE. For example, the connection electrode BE may be disposed on a portion of the protective layer INS of each light emitting element LE.

The connection electrode BE may include molybdenum (Mo), aluminum (Al), chromium (Cr), gold (Au), titanium (Ti), nickel (Ni), neodymium (Nd), and/or copper (Cu). Alternatively, the connection electrode BE may be made of a transparent conductive material (TCO) that can transmit light, such as indium tin oxide (ITO) and/or indium zinc oxide (IZO).

When the connection electrode BE is made of a metal material with high reflectivity such as aluminum (Al), light travelling in a lateral direction of each light emitting element LE from among light emitted from the active layer MQW of the light emitting element LE may be reflected by the connection electrode BE toward the top of the light emitting element LE. Accordingly, a loss of light of the light emitting element LE can be reduced, and thus the light efficiency of the light emitting element LE can be increased.

A second organic layer 211 is a layer for flattening steps caused by the light emitting elements LE. The second organic layer 211 may partially cover the side surfaces of the light emitting elements LE. In addition, the second organic layer 211 may cover the connection electrode BE. In the drawings, the second organic layer 211 entirely covers the side surfaces of the protective layer INS and partially covers the side surfaces of the second semiconductor layer SEM2. However, the present disclosure is not limited thereto. The second organic layer 211 may also cover the side surfaces of the protective layer INS, but may expose at least a portion of each side surface of the protective layer INS, that is, an upper portion of each side surface of the protective layer INS. The second organic layer 211 may have the first common connection hole CT4 that penetrates the second organic layer 211 and the first organic layer 210.

The second organic layer 211 may be made of an organic layer such as acryl resin, epoxy resin, phenolic resin, polyamide resin, and/or polyimide resin.

The common electrode CE may be disposed on an upper surface of the second organic layer 211. In addition, the common electrode CE may be disposed on a portion of the side surfaces of each light emitting element LE. The common electrode CE may be a common layer commonly formed in a first subpixel SPX1, a second subpixel SPX2 and a third subpixel SPX3 of the display area DA, but may expose the third semiconductor layer SEM3 of each light emitting element LE. The common electrode CE may be connected to the second power supply line VSL through a common connection hole CT4, CT5, or CT6 and may receive the second power supply voltage VSS.

The common electrode CE may be in contact with the side surfaces of the second semiconductor layer SEM2 or/and the third semiconductor layer SEM3 that are not covered with the protective layer INS. The common electrode CE may be in contact with the second semiconductor layer SEM2 having low resistance, and the common electrode CE and each light emitting element LE may be electrically connected. In one or more embodiments, the common electrode CE may also be in contact with the third semiconductor layer SEM3. A contact area between the common electrode CE and the third semiconductor layer SEM3 may be smaller than a contact area between the common electrode CE and the second semiconductor layer SEM2. The common electrode CE may be disposed on a portion of each side surface of the third semiconductor layer SEM3 and may not be disposed on the other portion of each side surface of the third semiconductor layer SEM3. In one or more embodiments, the common electrode CE may not be disposed on the light emitting elements LE. The resistance of the display device 10 can be reduced by reducing the contact area between the common electrode CE and the high-resistance third semiconductor layer SEM3 and increasing the contact area between the common electrode CE and the low-resistance second semiconductor layer SEM2.

The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE. The first capping layer CAP1 covers components disposed thereunder, such as the light emitting elements LE and the common electrode CE, to protect them from moisture and/or foreign substances.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the second organic layer 211 and the common electrode CE in the third direction DR3 and may not overlap the light emitting elements LE.

The first light conversion layer QDL1 may convert a portion of third light (e.g., light in the blue wavelength band) incident from a light emitting element LE into first light (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (e.g., light in the blue wavelength band) incident from the light emitting element LE into the first light (e.g., light in the red wavelength band).

The second light conversion layer QDL2 may convert a portion of third light (e.g., light in the blue wavelength band) incident from a light emitting element LE into second light (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (e.g., light in the blue wavelength band) incident from the light emitting element LE into the second light (e.g., light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 and/or a length of the first light blocking layer BM1 in the second direction DR2 may be greater than a length of the second light blocking layer BM2 in the first direction DR1 and/or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of any one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, silicon nitride (SiNₓ), silicon oxynitride (SiON), silicon oxide (SiOₓ), titanium oxide (TiOₓ), and/or aluminum oxide (AlOₓ).

A third capping layer CAP3 may be disposed on the second capping layer CAP2, the reflective layer RF, the first light conversion layer QDL1, the second light conversion layer QDL2, and the light transmission layer TPL.

The first capping layer CAP1, the second capping layer CAP2, and the third capping layer CAP3 may be made of an inorganic layer, for example, silicon nitride (SiNₓ), silicon oxynitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A third organic layer 213 may be disposed on the third capping layer CAP3. A plurality of color filters CF1 through CF3 may be disposed on the third organic layer 213. The color filters CF1 through CF3 may include first color filters CF1, second color filters CF2, and third color filters CF3.

A first color filter CF1 disposed in the first subpixel SPX1 may transmit first light (e.g., light in the red wavelength band) and absorb or block third light (e.g., light in the blue wavelength band). Therefore, the first color filter CF1 may transmit the first light (e.g., light in the red wavelength band) into which a portion of the third light (e.g., light in the blue wavelength band) emitted from a light emitting element LE has been converted by the first light conversion layer QDL1 and may absorb or block the third light (e.g., light in the blue wavelength band) which has not been converted by the first light conversion layer QDL1. Accordingly, the first subpixel SPX1 may output the first light (e.g., light in the red wavelength band).

A second color filter CF2 disposed in the second subpixel SPX2 may transmit second light (e.g., light in the green wavelength band) and absorb or block third light (e.g., light in the blue wavelength band). Therefore, the second color filter CF2 may transmit the second light (e.g., light in the green wavelength band) into which a portion of the third light (e.g., light in the blue wavelength band) emitted from a light emitting element LE has been converted by the second light conversion layer QDL2 and may absorb or block the third light (e.g., light in the blue wavelength band) which has not been converted by the second light conversion layer QDL2. Accordingly, the second subpixel SPX2 may output the second light (e.g., light in the green wavelength band).

A third color filter CF3 disposed in the third subpixel SPX3 may transmit third light (e.g., light in the blue wavelength band). Therefore, the third color filter CF3 may transmit the third light (e.g., light in the blue wavelength band) that passes through the light transmission layer TPL after being emitted from a light emitting element LE. Accordingly, the third subpixel SPX3 may emit the third light (e.g., light in the blue wavelength band).

The first color filter CF1, the second color filter CF2, and the third color filter CF3 overlapping each other in the third direction DR3 may overlap the light blocking layer BM in the third direction DR3.

A fourth organic layer 214 for planarization may be disposed on the color filters CF1 through CF3.

The third organic layer 213 and the fourth organic layer 214 may be made of acryl resin, epoxy resin, phenolic resin, polyamide resin, and/or polyimide resin.

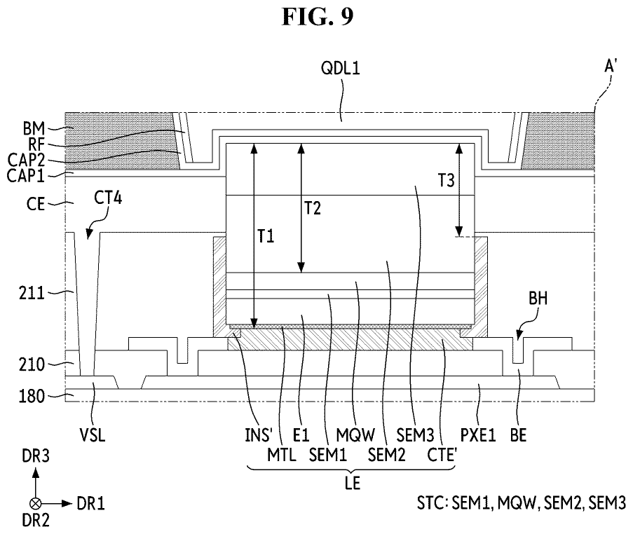

FIG. 9 is an enlarged cross-sectional view of a portion of a display panel 100 according to one or more embodiments.

FIG. 9 is different from FIG. 7 in that a protective layer INS′ is not disposed on a center of a lower surface of a metal layer MTL, but is disposed only on edges of the lower surface of the metal layer MTL. An area where the lower surface of the metal layer MTL is exposed without being covered with the protective layer INS′ may increase, and a contact area between the lower surface of the metal layer MTL and a contact electrode CTE′ may also increase. The contact electrode CTE′ and the metal layer MTL may be in contact with each other in one area. The disposition of the protective layer INS′ is not limited to that in FIG. 9 and may also be modified in various ways.

A process of manufacturing a display device 10 according to one or more embodiments will now be described with reference to other drawings.

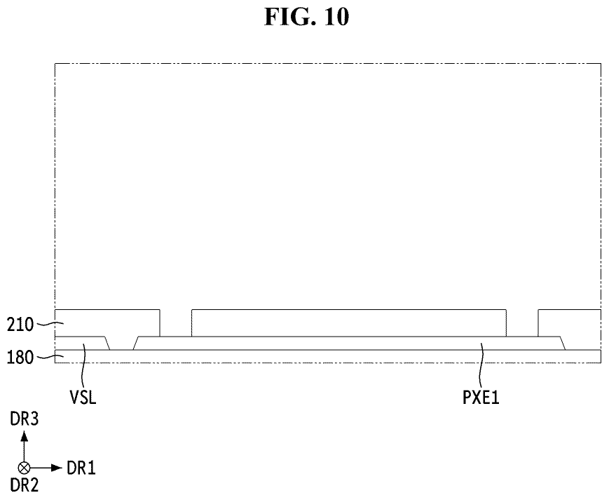

FIGS. 10 through 16 are cross-sectional views sequentially illustrating a process of manufacturing a display device according to one or more embodiments.

FIGS. 10 through 16 are cross-sectional views respectively illustrating structures according to the formation order of layers of the display device 10. FIGS. 10 through 16 mainly illustrate a process of manufacturing a light emitting element LE, a second organic layer 211 and a common electrode CE, and each of them may generally correspond to the cross-sectional view of FIG. 7. Hereinafter, a light emitting element LE of a first subpixel SPX1 will be mainly described.

In one or more embodiments, a thin-film transistor layer TFTL may be placed on a substrate SUB, and the structure of the thin-film transistor layer TFTL is the same as that described above with reference to FIG. 6. A detailed description of these elements will be omitted.

Referring to FIG. 10, a pixel electrode PXE1, PXE2, and/or PXE3 and a second power supply line VSL spaced (e.g., spaced apart) from each other may be formed on a second planarization layer 180, and a first organic layer 210 may be formed on the pixel electrode PXE1, PXE2, and/or PXE3 and the second power supply line VSL. The pixel electrode PXE1, PXE2, and/or PXE3 and the second power supply line VSL may be formed concurrently (e.g., simultaneously) and may be formed by a photo patterning process. The first organic layer 210 may be partially removed by the photo patterning process to expose at least a portion of the pixel electrode PXE1, PXE2, and/or PXE3.

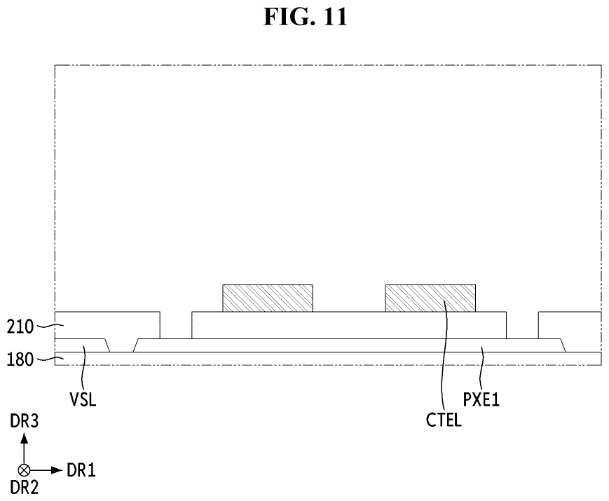

Next, referring to FIG. 11, a contact electrode material layer CTEL may be formed on the pixel electrode PXE1, PXE2, and/or PXE3. The contact electrode material layer CTEL may be a photoresist and may include a carbon material. The contact electrode material layer CTEL may be provided in multiple pieces on the pixel electrode PXE1, PXE2, and/or PXE3, but the present disclosure is not limited thereto. The contact electrode material layer CTEL may also be provided in one piece on the pixel electrode PXE1, PXE2, and/or PXE3. The contact electrode material layer CTEL may be placed on each pixel electrode PXE1, PXE2, and/or PXE3 by a photo patterning process.

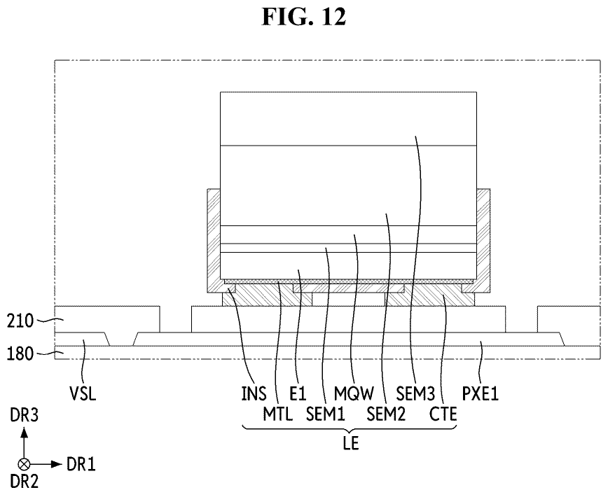

Next, referring to FIG. 12, a body portion of the light emitting element LE having a protective layer INS on its side surfaces may be prepared, and the body portion of the light emitting element LE may be placed on the contact electrode material layer CTEL to bond the body portion of the light emitting element LE and the substrate together. At this time, the body portion of the light emitting element LE may be placed such that a metal layer MTL not covered with the protective layer INS is in contact with the contact electrode material layer CTEL. The contact electrode material layer CTEL may become a contact electrode CTE having conductivity by receiving pressure from the body portion of the light emitting element LE. The body portion of the light emitting element LE may include the metal layer MTL, a conductive layer E1, a first semiconductor layer SEM1, an active layer MQW, a second semiconductor layer SEM2, and a third semiconductor layer SEM3. A portion of each side surface of the body portion of the light emitting element LE may be covered with the protective layer INS, and the other portion may not be covered with the protective layer INS.

The body portion of the light emitting element LE may be manufactured using a known method of manufacturing a vertical type micro-light emitting diode. After a protective material layer is formed to cover an outer surface of the body portion of the manufactured light emitting element LE, it may be removed from a portion of a lower surface and a portion of each side surface of the light emitting element LE to form the protective layer INS.

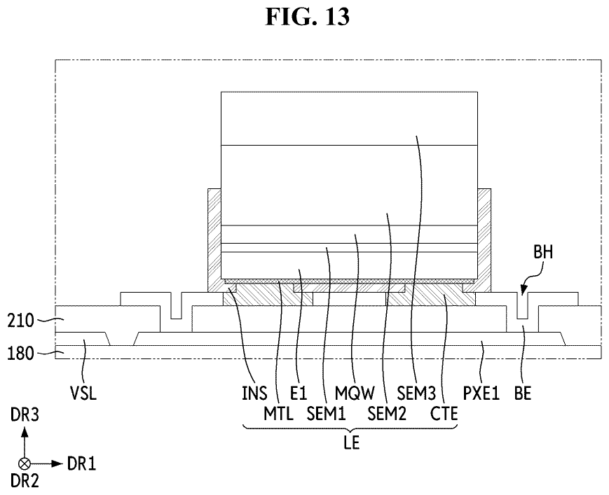

Next, referring to FIG. 13, a connection electrode BE may be formed on the pixel electrode PXE1, PXE2, and/or PXE3 and the first organic layer 210. The connection electrode BE may be in contact with the contact electrode CTE and may also be in contact with the pixel electrode PXE1, PXE2, and/or PXE3 through a connection hole BH penetrating the first organic layer 210. The connection electrode BE may have conductivity and electrically connect the body portion of the light emitting element LE and the pixel electrode PXE1, PXE2 or PXE3.

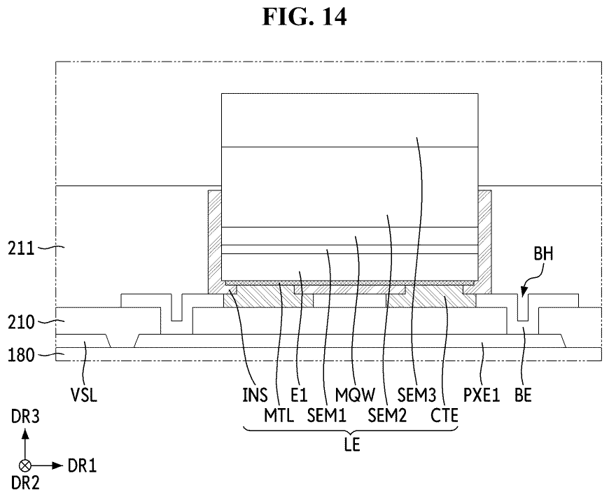

Next, referring to FIG. 14, a second organic layer 211 may be formed on the connection electrode BE and the first organic layer 210. Side surfaces of the second semiconductor layer SEM2 or/and the third semiconductor layer SEM3 of the light emitting element LE have an open area not covered with the protective layer INS. The second organic layer 211 may be formed up to the open area of the side surfaces of the second semiconductor layer SEM2 and the third semiconductor layer SEM3. The second organic layer 211 may be formed to expose at least a portion of the open area of the side surfaces of the second semiconductor layer SEM2 and the third semiconductor layer SEM3.

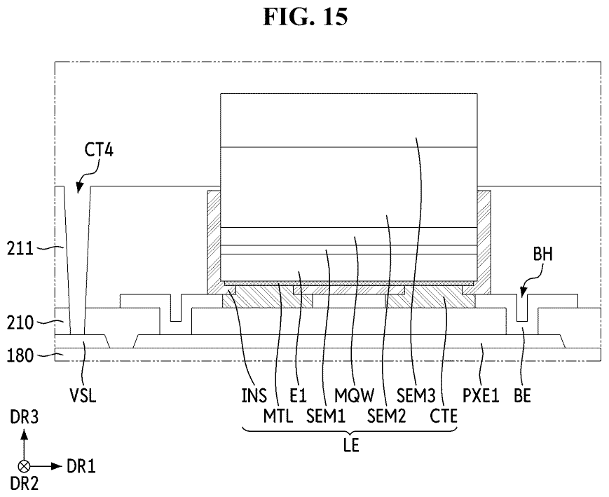

Next, referring to FIG. 15, a common connection hole CT4 penetrating the second organic layer 211 and the first organic layer 210 may be formed at a position overlapping the second power supply line VSL.

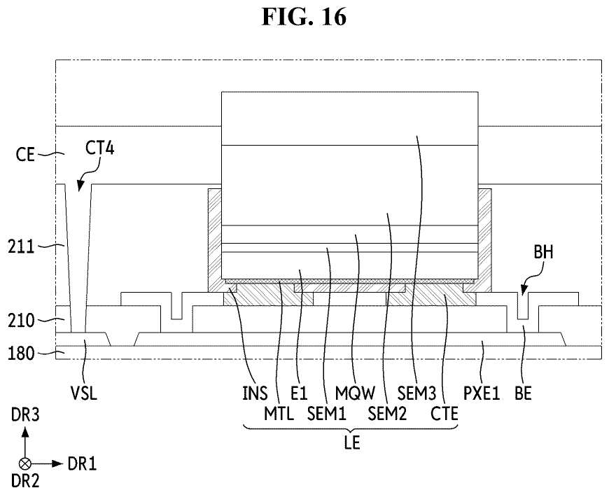

Next, referring to FIG. 16, a common electrode CE is formed on the second organic layer 211. The common electrode CE may be in contact with the side surfaces of the second semiconductor layer SEM2 or/and the third semiconductor layer SEM3. The common electrode CE may not be formed on an upper surface of the third semiconductor layer SEM3.

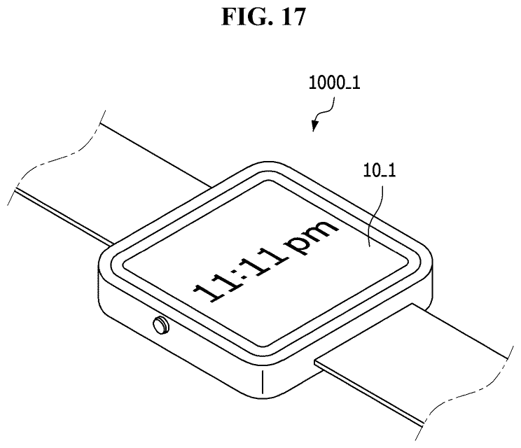

FIG. 17 is an example view of a smart watch including a display device according to one or more embodiments. Referring to FIG. 17, a display device 10_1 according to one or more embodiments may be applied to a smart watch 1000_1 which is one of smart devices.

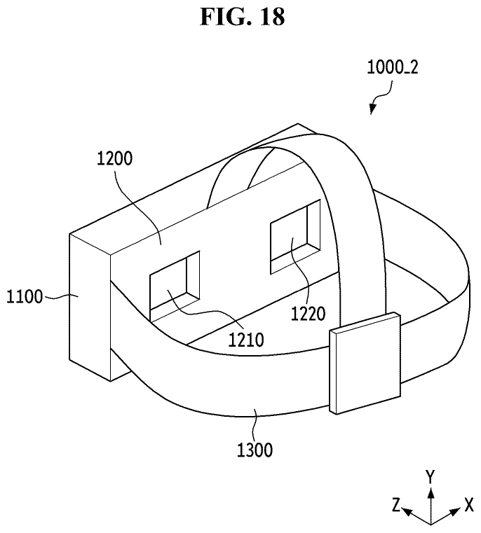

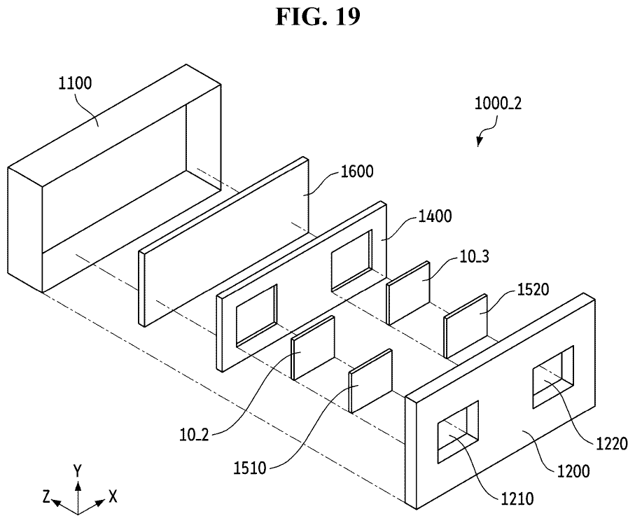

FIGS. 18 and 19 are example views of a virtual reality (VR) device including a display device according to one or more embodiments.

Referring to FIGS. 18 and 19, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 18 and 19, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

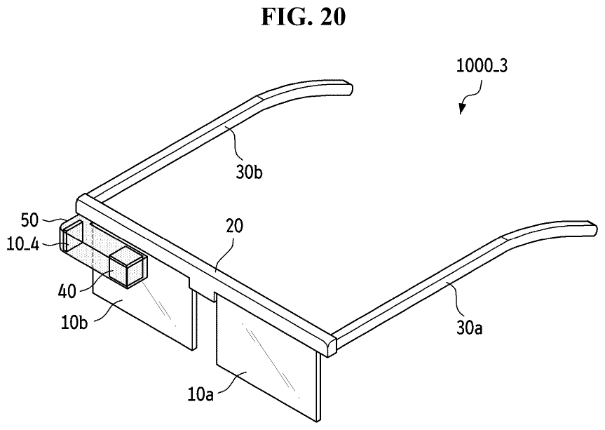

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 20 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 20 is an example view of a VR device including a display device according to one or more embodiments. FIG. 20 illustrates a VR device 1000_3 to which a display device 10_4 according to one or more embodiments has been applied.

Referring to FIG. 20, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 20, a case where the VR device 1000_3 is a glasses-type display device including the eyeglass frame legs 30a and 30b is illustrated as an example. That is, the VR device 1000_3 according to the embodiment is not limited to the one illustrated in FIG. 20 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 20, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

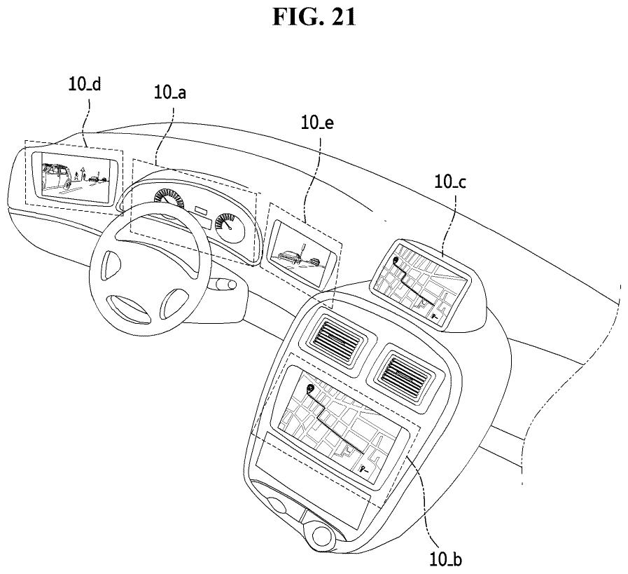

FIG. 21 is an example view illustrating a vehicle instrument cluster and center fascia including display devices according to one or more embodiments. FIG. 21 illustrates a vehicle to which display devices 10_a through 10_e according to one or more embodiments have been applied.

Referring to FIG. 21, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

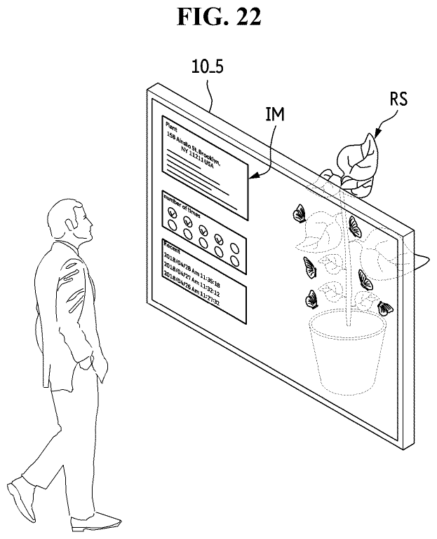

FIG. 22 is an example view of a transparent display device including a display device according to one or more embodiments.

Referring to FIG. 22, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

The display device according to one or more embodiments of the present disclosure may be applied to various electronic devices. The electronic device according to the one or more embodiments of the present disclosure includes the display device described above, and may further include modules or devices having additional functions in addition to the display device.

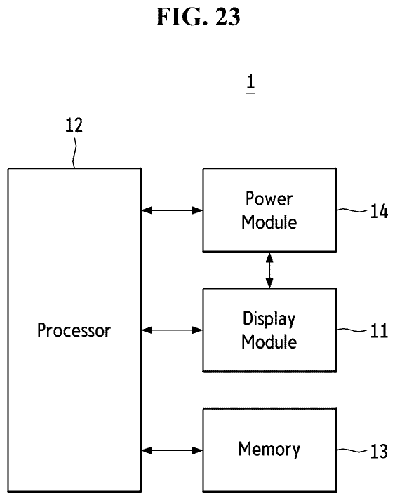

FIG. 23 is a block diagram of an electronic device according to one or more embodiments of the present disclosure.

Referring to FIG. 23, the electronic device 1 according to one or more embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and/or a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

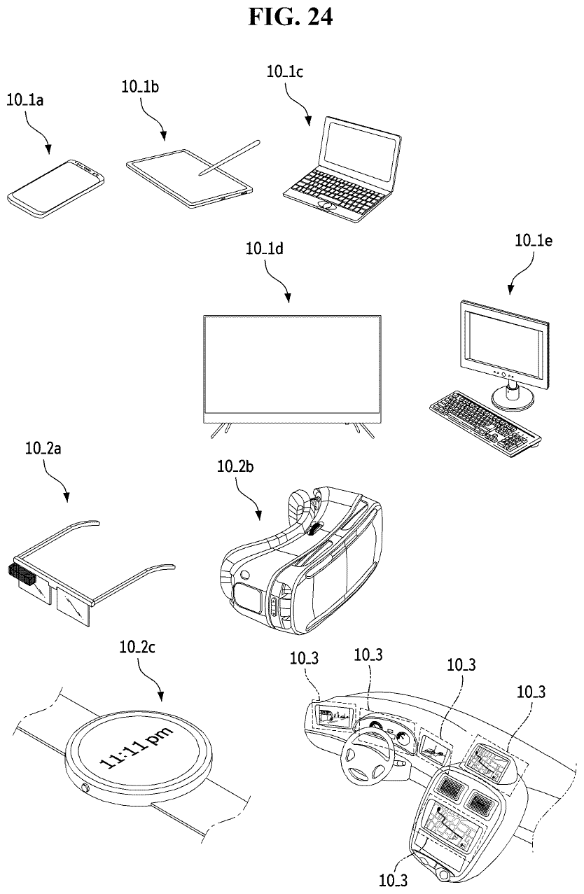

FIG. 24 is a schematic diagram of an electronic device according to various embodiments of the present disclosure.

Referring to FIG. 24, various electronic devices to which display devices 10 according to embodiments of the present disclosure are applied may include not only image display electronic devices such as a smart phone 10_1a,a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein. what is claimed is:

1. A display device comprising:
a first pixel electrode on a substrate;
a first light emitting element on the first pixel electrode and comprising a semiconductor stack and a protective layer; and
a common electrode on the substrate,
wherein a side surface of the semiconductor stack comprises a first portion and a second portion that are different from each other, wherein the protective layer is on the first portion of the side surface of the semiconductor stack, and the common electrode is on the second portion of the side surface of the semiconductor stack.

2. The display device of claim 1, wherein the first portion is closer to the first pixel electrode than the second portion.

3. The display device of claim 1, wherein the common electrode is in contact with the second portion of the side surface of the semiconductor stack.

4. The display device of claim 1, wherein the semiconductor stack comprises a first semiconductor layer, an active layer, and a second semiconductor layer stacked sequentially on the first pixel electrode, and the first portion of the side surface of the semiconductor stack comprises the first semiconductor layer.

5. The display device of claim 4, wherein the second portion of the side surface of the semiconductor stack comprises the second semiconductor layer.

6. The display device of claim 4, wherein the semiconductor stack further comprises a third semiconductor layer on the second semiconductor layer, and the second portion of the side surface of the semiconductor stack comprises the third semiconductor layer.

7. The display device of claim 1, further comprising a capping layer on the first light emitting element and the common electrode.

8. The display device of claim 7, wherein the capping layer is on the second portion of the side surface of the semiconductor stack.

9. The display device of claim 6, wherein a thickness of the second portion of the side surface of the semiconductor stack is 50% or more of a sum of thicknesses of the second semiconductor layer and the third semiconductor layer of the first light emitting element.

10. The display device of claim 1, wherein a thickness of the second portion of the side surface of the semiconductor stack is 1.1 to 2.7 μm.

11. The display device of claim 1, wherein the common electrode comprises one or more of indium tin oxide (ITO), zinc indium tin oxide (ZITO), and/or indium zinc oxide (IZO).

12. The display device of claim 1, wherein the first light emitting element further comprises a contact electrode between the first pixel electrode and the semiconductor stack, and the contact electrode comprises a conductive carbon material.

13. The display device of claim 12, wherein the first light emitting element further comprises a metal layer between the semiconductor stack and the first pixel electrode, wherein the protective layer partially covers a lower surface of the metal layer to expose at least a portion of the lower surface of the metal layer, and the contact electrode is in contact with the exposed lower surface of the metal layer.

14. The display device of claim 1, further comprising:
a second pixel electrode on the substrate and spaced from the first pixel electrode; and
a second light emitting element on the second pixel electrode and comprising a semiconductor stack and a protective layer,
wherein the common electrode is on a side surface of the second light emitting element.

15. The display device of claim 1, further comprising:
a power supply line on the substrate and spaced from the first pixel electrode; and
an organic layer between the power supply line and the common electrode,
wherein the organic layer includes a common connection hole penetrating the organic layer, and
wherein the power supply line and the common electrode are electrically connected through the common connection hole.

16. A display device comprising:
a plurality of pixel electrodes on a substrate;
a plurality of light emitting elements on the plurality of pixel electrodes, respectively; and
a common electrode on the substrate and in contact with side surfaces of the plurality of light emitting elements,
wherein each of the plurality of light emitting elements comprises a body portion comprising a metal layer, a first semiconductor layer, an active layer, a second semiconductor layer, and a third semiconductor layer stacked sequentially and a protective layer on an edge of a lower surface of the body portion, and the protective layer extends on the edge of the lower surface of the body portion to cover a portion of a side surface of the body portion and exposes an other portion of the side surface of the body portion.

17. The display device of claim 16, wherein the side surface of the body portion that is not covered with the protective layer is in contact with the common electrode.

18. The display device of claim 16, wherein a thickness of the side surface of the body portion that is not covered with the protective layer is 40% or more of a thickness of the body portion.

19. The display device of claim 16, wherein at least a portion of a side surface of the second semiconductor layer is exposed without being covered with the protective layer.

20. The display device of claim 16, further comprising a capping layer on upper and side surfaces of the third semiconductor layer.

21. An electronic device, comprising:
a display device configured to provide an image;
a processor configured to provide an image data signal into the display device, and
wherein the display device comprises:
a first pixel electrode on a substrate;
a first light emitting element on the first pixel electrode and comprising a semiconductor stack and a protective layer; and
a common electrode on the substrate,
wherein a side surface of the semiconductor stack comprises a first portion and a second portion that are different from each other, wherein the protective layer is on the first portion of the side surface of the semiconductor stack, and the common electrode is on the second portion of the side surface of the semiconductor stack.
